(19) United States
(12) Patent Application Publication
(10) Pub. No.: US 2026/0198260 A1
(43) Pub. Date: Jul. 9, 2026

(54) ION IMPLANTER

(71) Applicant: NISSIN ION EQUIPMENT CO., LTD., Koka-city (JP)

(72) Inventor: Masatoshi ONODA, Koka-city (JP)

(73) Assignee: NISSIN ION EQUIPMENT CO., LTD., Koka-city (JP)

(21) Appl. No.: 19/437,505

(22) Filed: Dec. 31, 2025

(30) Foreign Application Priority Data
Jan. 9, 2025 (JP) 2025-003146

(51) Int. Cl. H10P 72/30; H01J 37/317

(52) U.S. Cl. CPC H10P 72/3302; H01J 37/3171; H10P 72/3304; H01J 2237/20228

(57) ABSTRACT

An ion implanter includes a process chamber, two holders to be scanned linearly across an ion beam in the process chamber, the two holders including a first holder that supports a single wafer and a second holder that supports one or more wafers; and a controller that selects only the first holder, only the second holder, or both the first holder and the second holder to be scanned from the two holders during ion implantation into plural wafers. When a number of wafers to be processed is N and a number of wafers supported by the second holder is M, the controller selects the holders to be scanned to satisfy a relationship N = (1 + M) × A + B + M × C. Each of A, B, and C is 0 or a natural number, and one or more of A, B, and C is not 0.

### CROSS REFERENCE TO RELATED APPLICATIONS

This application is based on and claims priority from Japanese Patent Application No. 2025-003146, filed in the Japan Patent Office on January 9, 2025, the contents of which being incorporated by reference herein in its entirety.

### BACKGROUND

### Field

The present disclosure relates to an ion implanter configured to process a plurality of wafers.

### Description of Related Art

As an ion implanter, a single-wafer type ion implanter that processes wafers one by one and a batch type ion implanter that processes a plurality of wafers collectively are known. Each type has its own advantages and disadvantages, but when the number of wafers processed per unit time is prioritized, a batch type ion implanter tends to be used.

### SUMMARY

According to an aspect of one or more embodiments, an ion implanter may include a process chamber; two holders configured to be scanned linearly across an ion beam in the process chamber, the two holders comprising a first holder configured to support a single wafer and a second holder configured to support one or more wafers; and a controller configured to select only the first holder, only the second holder, or both the first holder and the second holder to be scanned from the two holders during ion implantation into a plurality of wafers. The controller may be configured such that, when a number of wafers of the plurality of wafers to be processed is N and a number of wafers supported by the second holder is M, the controller selects the holders to be scanned to satisfy a relationship N = (1 + M) × A + B + M × C, and A is a number of times both the first holder and the second holder are selected, B is a number of times only the first holder is selected, and C is a number of times only the second holder is selected. Each of A, B, and C is 0 or a natural number, and at least one of A, B, or C is not 0.

According to another aspect of one or more embodiments, an ion implanter may include a process chamber; two holders configured to be scanned linearly across an ion beam in the process chamber during an ion implantation of a plurality of wafers, the ion implantation including a plurality of ion implantation processes, the two holders comprising a first holder configured to support a single wafer and a second holder configured to support one or more wafers; and a controller configured to select, for each ion implantation process of the plurality of ion implantation processes, only the first holder, only the second holder, or both the first holder and the second holder to be scanned. When a number of wafers of the plurality of wafers to be processed is N and a number of wafers supported by the second holder is M, the ion implantation of the plurality of wafers satisfies a relationship N = (1 + M) × A + B + M × C, wherein A is a number of times both the first holder and the second holder are selected during the ion implantation, B is a number of times only the first holder is selected during the ion implantation, and C is a number of times only the second holder is selected during the ion implantation, and wherein each of A, B, and C is 0 or a natural number, and at least one of A, B, or C is not 0.

### BRIEF DESCRIPTION OF THE DRAWINGS

The above and/or other aspects will become apparent and more readily appreciated from the following description of various embodiments, taken in conjunction with the accompanying drawings, in which:

FIG. 1 illustrates an example of a schematic configuration view of an ion implanter, according to some embodiments;

FIG. 2 illustrates an example of a schematic plan view of each holder in the ion implanter of FIG. 1 as viewed from the Z-axis direction, according to some embodiments;

FIG. 3 illustrates an example of an explanatory diagram of a selection process of a controller C, according to some embodiments;

FIG. 4 illustrates an example of an explanatory diagram of a selection process of a controller C, according to some embodiments;

FIG. 5 illustrates an example of an explanatory diagram of a selection process of a controller C, according to some embodiments;

FIG. 6 illustrates an example of an explanatory diagram of a selection process of a controller C, according to some embodiments;

FIG. 7 illustrates an example of a schematic configuration view of an ion implanter, according to some embodiments;

FIG. 8 illustrates an example of a schematic plan view of each holder of the ion implanter in FIG. 7 as viewed from the Z-axis direction, according to some embodiments;

FIG. 9 illustrates an example of an explanatory diagram of a selection process of a controller C in the ion implanter shown in FIG. 7, according to some embodiments;

FIG. 10 illustrates an example of a schematic plan view of a second holder, according to some embodiments;

FIG. 11 illustrates an example of a schematic plan view of the second holder, according to some embodiments;

FIG. 12 illustrates an example of a schematic configuration view of an ion implanter, according to some embodiments; and

FIG. 13 illustrates an example of a schematic configuration view of an implanter, according to some embodiments.

### DETAILED DESCRIPTION

Hereinafter, various embodiments of the present disclosure will be described with reference to the drawings. In all the drawings for explaining the various embodiments, common components are denoted by the same reference numerals, and repeated description thereof will be omitted for conciseness. The following embodiments do not unduly limit the contents of the present disclosure described in the appended claims. Further, all the components shown in the embodiments are not necessarily essential components of the present disclosure. Each drawing is a schematic view and is not necessarily intended to illustrate various dimensions strictly.

In a batch type ion implanter, a predetermined number of holders are equipped with wafers, and ion implantation is performed collectively on the wafers. When the number of wafers to be processed is less than the number of holders, dummy wafers are used to fill the shortage.

When a wafer support member holding a dummy wafer is scanned for ion implantation, the dummy wafer is also irradiated with an ion beam. The dummy wafer deteriorates due to sputtering by the ion beam, and when the dummy wafer deteriorates, the dummy wafer must be replaced with a new dummy wafer. The need to replace dummy wafers increases the cost required for wafer processing, which may be a disadvantage.

To reduce the cost of dummy wafers, inexpensive wafers may be used as dummy wafers. However, if a dummy wafer of a different type from the wafer to be processed is used, the load on the holder may become unbalanced. Scanning the holder in an unbalanced state may cause shaking or vibration, leading to defective ion implantation. For this reason, typically the same wafer as the wafer to be processed is used as a dummy wafer. However, if the wafer to be processed is expensive, using the wafer to be processed as a dummy wafer may further increase the processing cost.

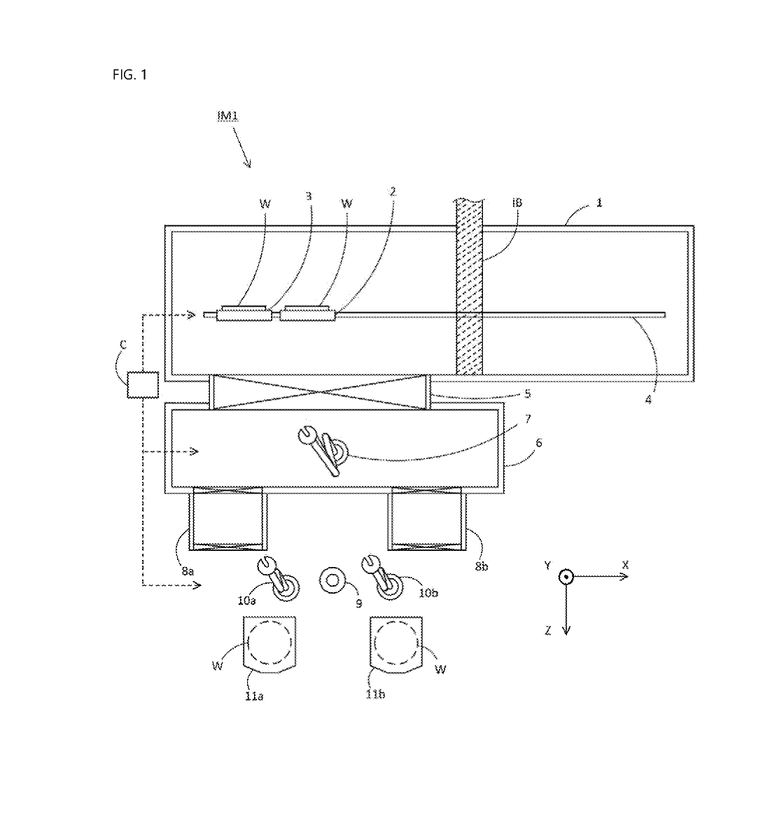

FIG. 1 shows a schematic configuration view of an ion implanter IM1, according to some embodiments. An ion beam IB may travel in a Z-axis direction and may be irradiated into a process chamber 1. The ion beam IB may be a ribbon beam elongated in a Y-axis direction. In some embodiments, the ion beam may be a spot beam scanned in the Y-axis direction. In an embodiment, the ion implanter IM1 may include the process chamber 1, a valve 5, a transfer chamber 6, load-lock chambers 8a, 8b, atmospheric transfer robots 10a, 10b, an aligner 9, cassettes 11a, 11b, and a controller C.

On the upstream side (opposite to the Z-axis direction) of the process chamber 1, a beamline (not shown) forming a transport path of the ion beam IB and an ion source (not shown) generating the ion beam IB are provided. During operation of the ion implanter IM1, the ion source, the beamline, and the process chamber 1 may all be under a vacuum atmosphere.

In the process chamber 1, two holders including a first holder 2 and a second holder 3 may be provided, which are scanned linearly across the ion beam IB. The first holder 2 may be configured to support a single wafer W and the second holder 3 may be configured to support a single wafer W.

Each of the first and second holders 2 and 3 may be linearly scanned along a guide rail 4, which serves as a scanning path, in the X-axis direction by a drive mechanism (not shown).

On an atmospheric side, the cassettes 11a and 11b, each storing a plurality of wafers W, are arranged in the Y-axis direction. Each cassette 11a, 11b is provided with multiple shelves in the Y-axis direction for storing wafers W in the Y-axis direction. The transfer of wafers W from cassettes 11a, 11b to each of the first and second holders 2, 3 will be described further below.

On the atmospheric side, the atmospheric transfer robots 10a and 10b are arranged. For example, in an embodiment, two of the atmospheric transfer robots 10a and 10b may be provided. The atmospheric transfer robots 10a and 10b are equipped with horizontal hands capable of changing height in the Y-axis direction and moving in various directions within the ZX plane.

Each atmospheric transfer robot 10a, 10b may take a wafer W from a respective one of the cassettes 11a, 11b and transfer the wafer W to the aligner 9. While FIG. 1 illustrates one aligner 9, embodiments are not limited thereto and, in some embodiments, a plurality of the aligner 9 may be provided. In the aligner 9, a circumferential position of the wafer W may be adjusted based on a notch or orientation flat of the wafer W.

If only one aligner 9 is provided, the position adjustment of wafers W transferred from each atmospheric transfer robot 10a, 10b may be performed sequentially. If multiple aligners 9 are provided, the position adjustment of wafers W transferred from each atmospheric transfer robot 10a, 10b may be performed simultaneously. When multiple aligners 9 are provided, for example, the multiple aligners 9 may be arranged side by side in the Y-axis direction.

After the position adjustment at the aligner 9 is completed, each atmospheric transfer robot 10a, 10b may transfer the wafer W to a corresponding load-lock chamber 8a, 8b.

When the wafer W is transferred to each load-lock chamber 8a, 8b, the inside of the load-lock chamber 8a, 8b may become a sealed space. Thereafter, evacuation of the load-lock chamber 8a, 8b may be started.

After the degree of vacuum in each load-lock chamber 8a, 8b reaches a level similar to a degree/level of vacuum of the process chamber 1, a valve on a transfer chamber 6 side of each load-lock chamber 8a, 8b may be opened.

A vacuum transfer robot 7 is arranged in the transfer chamber 6. The vacuum transfer robot 7 may be, for example, a horizontal articulated robot, but embodiments are not limited thereto and, in some embodiments, the vacuum transfer robot 7 may be a vacuum transfer robot composed of a rail and a swivel arm.

The vacuum transfer robot 7 may sequentially take wafers W from each load-lock chamber 8a, 8b and transfer the wafers W to the first holder 2 and the second holder 3 in the process chamber 1. Unlike the configuration shown in FIG. 1, two vacuum transfer robots 7 may be provided to simultaneously transfer wafers W to the first holder 2 and the second holder 3.

Before transferring wafers W from the vacuum transfer robot 7 to the first holder 2 and the second holder 3, the valve 5, which opens and closes a passage between the process chamber 1 and the transfer chamber 6, may be opened.

In an embodiment, the valve 5 may be a small valve with an opening large enough for a single wafer W to pass through. In some embodiments, the valve 5 may be a large valve as shown in FIG. 1.

In the configuration example of FIG. 1, a width of the valve 5 in the X-axis direction is greater than a sum of diameters of two wafers W. This width makes it possible to transfer two wafers W simultaneously.

If the width of the valve 5 is small, the transfer location of wafers W to each of the first and second holders 2, 3 may be limited. For this reason, it is advantageous to adopt the valve 5 having a larger width, which is greater than the sum of the diameters of two wafers W, as shown in FIG. 1.

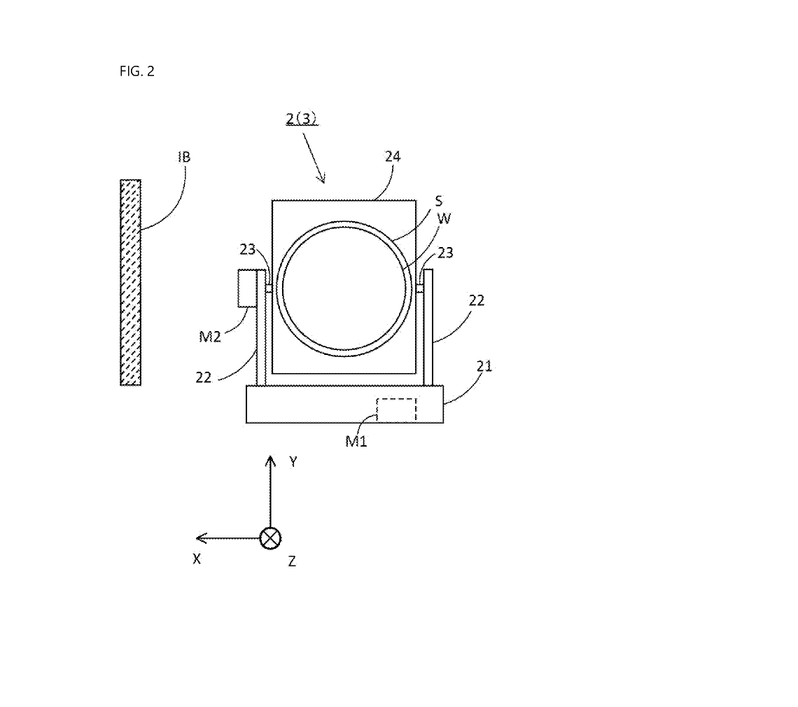

FIG. 2 illustrates an example of a schematic plan view of each of the first and second holders 2, 3 in the ion implanter IM1 of FIG. 1 as viewed from the Z-axis direction, according to some embodiments. In an embodiment, FIG. 2 shows a schematic plan view of the first holder 2 and the second holder 3, as seen from the Z-axis direction in FIG. 1. Each of the first and second holders 2, 3 may be provided with a base 21 configured to move along the guide rail 4, two arms 22, a rotation shaft 23, a drive source M2, and a support plate 24. The base 21 may incorporate a drive source M1 and a drive mechanism (not shown) driven by the drive source M1. For example, the drive source M1 may be a motor, an air supply, an air cylinder, exhaust, etc., and the drive mechanism may be one or more shafts and/or one or more gears, an actuator to move the air cylinder, etc. The two arms 22 may be vertically mounted on the base 21. The rotation shaft 23 may extend through each arm 22 at an end of each arm 22 opposite to the base 21, and the drive source M2 may be configured to rotate the rotation shaft 23 and thereby rotate the support plate 24, as illustrated in FIG. 2. In an embodiment, each arm 22 may have a separate rotation shaft 23 at the end thereof opposite to the base 21, and the drive source M2 may be provided with one of the rotation shafts 23 and configured to rotate the one of the rotation shafts 23 in order to rotate the support plate 24. In other words, the one of the rotations shafts 23 may be driven by the drive source M2 and the other of the rotation shafts 23 may be a pin, or similar structure that allows the support plate 24 to rotate about an axis extending through the rotation shafts 23.

In an embodiment, the drive source M2 may rotate the rotation shaft 23, causing the support plate 24 connected to the rotation shaft 23 to rotate. A support S may be placed on the support plate 24. The support S is a member configured to support a wafer W, and may comprise an electrostatic chuck, a mechanical clamp, or both.

In some embodiments, when transferring a wafer W to the first holder 2 or the second holder 3, the first or second holder 2, 3 may be rotated about the rotation shaft 23 parallel to the X-axis direction so that a support surface of the support S for the wafer W is parallel to the ZX plane. After the wafer W is transferred, the first or second holder 2, 3 may be rotated about the rotation shaft 23 parallel to the X-axis direction in the opposite direction. In the configuration of FIG. 2, the rotation shaft 23 may serve both as a shaft for setting the tilt angle of the wafer W and as a shaft for changing the orientation of the support plate 24 during wafer exchange.

In an embodiment, after transferring a wafer W to each of the first and second holders 2, 3 and before starting scanning on the guide rail 4, the valve 5 may be closed. As a result, during ion implantation process of the wafer W, the process chamber 1 and the transfer chamber 6 may be spatially separated.

In an embodiment, an ion implantation process may be performed by scanning each of the first and second holders 2, 3 on the guide rail 4. It is not always necessary for both of the first and second holders 2, 3 to be scanned. A controller C may determine which of the first and second holders 2, 3 to scan.

In an embodiment, the controller C may include a calculation process unit and a storage. The calculation process unit may be a microprocessor, a central processing unit, a microcontroller, hardware control logic, or a combination thereof. The calculation process unit may also be provided as a plurality of calculation process units. The storage may store program code for realizing various functions such as a storage function for storing data, a calculation function for calculating data, and a control function for controlling the transfer of the wafer W, and may store a number N of wafers to be processed and a number of wafers supported by each of the first and second holders 2, 3. The calculation process unit of the controller C may access the program code, the number N of wafers, and the number of wafers supported by each of the first and second holders 2, 3 stored in the storage to execute various functions. The number of wafers supported by each of the first and second holders 2, 3 refers to the number of wafers W that may be supported by the support S of each of the first and second holders2, 3.

In an embodiment, the controller C may select which of the first and second holders 2, 3 to scan when performing ion implantation process on the wafer W, based on the number N of wafers to be processed, the number of wafers supported by the first holder 2, and the number of wafers supported by the second holder 3.

The selection of the which of the first and second holders 2, 3 to scan refers to selecting whether to use both the first and second holders 2, 3 or only one of the first and second holders 2, 3 for ion implantation process.

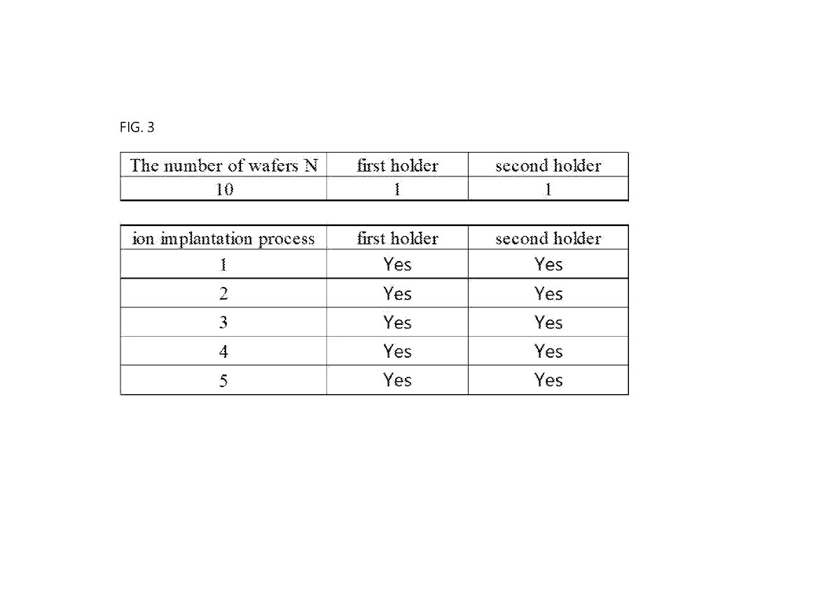

FIGS. 3 to 6 are explanatory diagrams of the selection process by the controller C, according to various embodiments. In the configuration of FIG. 1 and the selection process of FIG. 3, the number of wafers W supported by the first holder 2 and the second holder 3 is one each, and the number of wafers W to be processed is set to ten. During a sequential ion implantation process, processed wafers W may be exchanged with unprocessed wafers W.

In some embodiments, ion implantation process of the wafer W may be continuously performed on a certain number of wafers W after setting an implantation recipe including ion species, energy, beam current, dose amount, tilt angle, and/or twist angle.

The wafers W to be processed are wafers W stored in cassette 11a or cassette 11b, and are wafers W subjected to ion implantation process with a same implantation recipe.

In an embodiment as illustrated in FIG. 3, the controller C may select both the first holder 2 and the second holder 3 for each ion implantation process. It is conceivable to use only the first holder 2 for each ion implantation process. However, this selection would require ten ion implantation processes, significantly reducing the productivity of the ion implanter.

To avoid such a decrease in productivity, the controller C to use its calculation function and may derive a combination of holder selections that may perform a series of ion implantation processes in the shortest possible time. The controller C may select the holder to be scanned according to the derived combination.

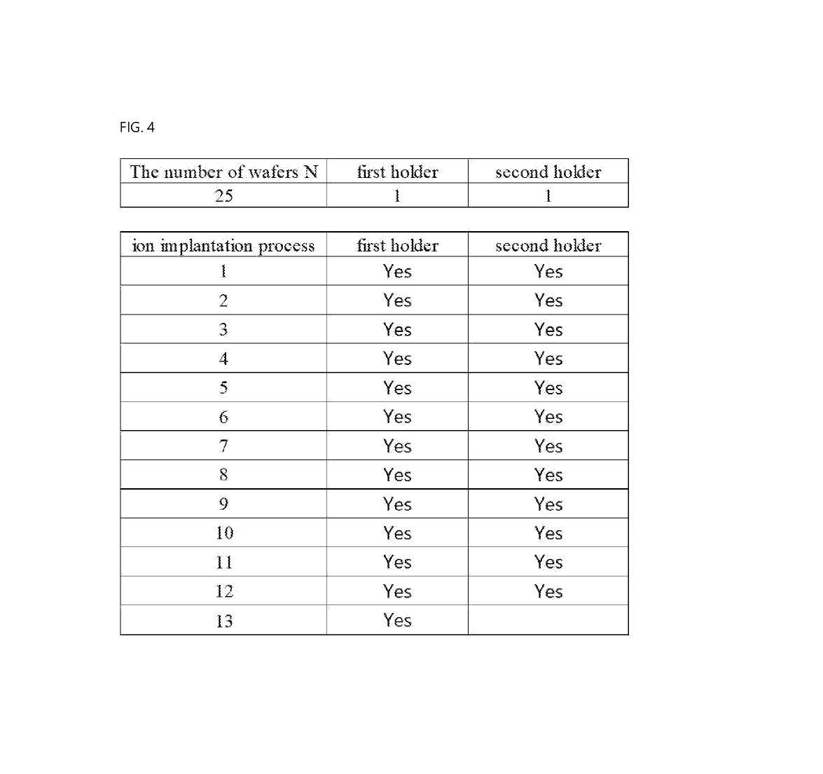

In the configuration of FIG. 1 and the selection process of FIG. 4, the number of wafers W to be processed is set to twenty-five. The controller C may select both the first holder 2 and the second holder 3 for the first to twelfth ion implantation processes. For the thirteenth ion implantation process, the controller C may select only the first holder 2. The second holder 3 that is not selected for the thirteenth ion implantation process may remain stationary on the guide rail 4 and thus may not be subjected to the ion beam.

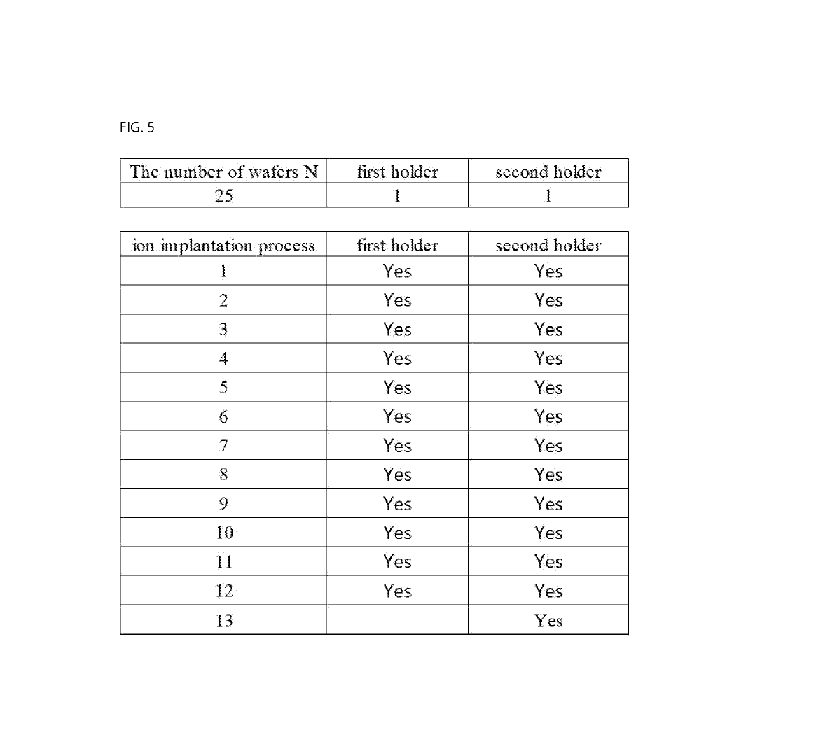

In the configuration of FIG. 1 and the selection process of FIG. 5, as in the selection process of FIG. 4, the number of wafers W to be processed is twenty-five. However, for the thirteenth ion implantation process, the controller C may select the second holder 3.

In the configuration shown in FIG. 1, the first holder 2 is positioned closer to the ion beam IB than the second holder 3. If the second holder 3 is selected last as in the selection process illustrated in FIG. 5, prior to the thirteenth ion implantation process, the irradiation of the ion beam IB to the process chamber 1 may be stopped. Thereafter, the first holder 2 may be retracted to the right end of the guide rail 4 so as not to interfere when the second holder 3 is scanned.

In some embodiments, after retracting the first holder 2, irradiation of the ion beam IB to the process chamber 1 may be resumed, and the second holder 3 may be scanned to perform ion implantation process on the wafer W.

As illustrated in the embodiments shown in FIGS. 3 and 4, the ion implantation process may be performed on each wafer without using a dummy wafer. However, if the second holder 3 is selected, it may be necessary to retract the first holder 2, which may prolong the total time for a series of ion implantation processes.

If either the first holder 2 or the second holder 3 may be selected, it is advantageous for the controller C to calculate the implantation time used when using each of the first and second holders 2, 3, and select the holder that will provide the shorter implantation time.

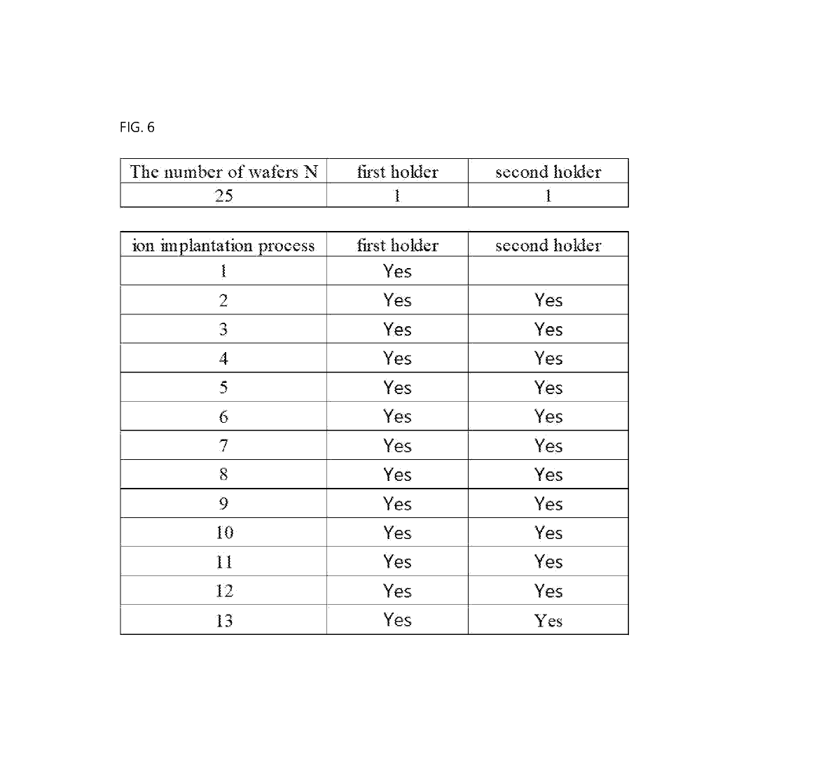

In the configuration of FIG. 1 and the selection process of FIG. 5, as with the selection process of FIG. 4, the number of wafers W to be processed is twenty-five. However, in a first ion implantation process, only the first holder 2 is selected. There is no difference in the total time used for the series of ion implantation processes between the combinations of holder selections shown in FIGS. 4 and 6.

Considering such points, the controller C may store in advance a rule regarding which ion implantation process should use a different holder selection from the other ion implantation processes. Then, at the stored count, the controller C may perform a holder selection different from the others.

The number of wafers W supported by the second holder 3 is not limited to one.

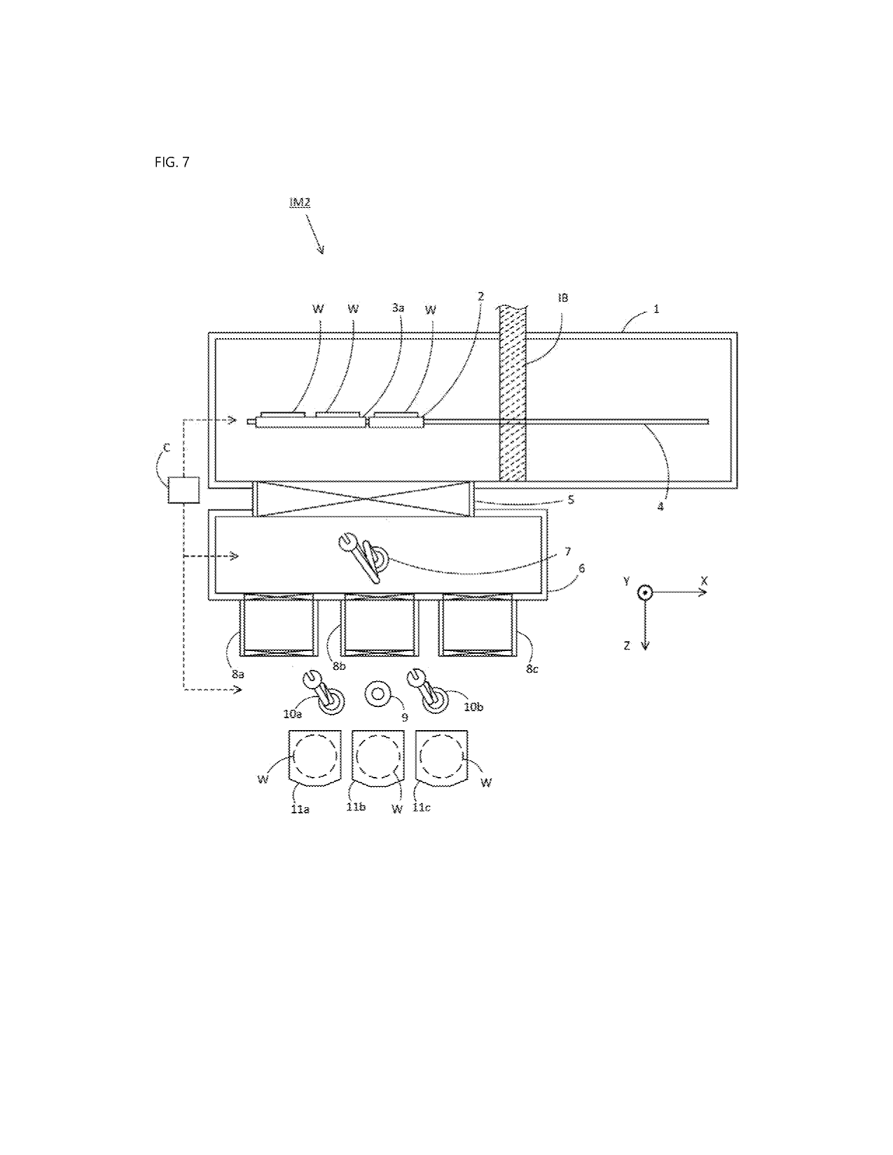

FIG. 7 illustrates an example of a schematic configuration view of an ion implanter, according to some embodiments. A configuration of an ion implanter IM2 is similar to a configuration of the ion implanter IM1 illustrated in FIG. 1 except for a configuration of the second holder, and for the components other than the second holder, the same reference designators are used for the same components and repeated description thereof is omitted for conciseness. The ion implanter IM2 may include a second holder 3a. In the ion implanter IM2 shown in FIG. 7, the number of wafers W supported by the second holder 3a is two.

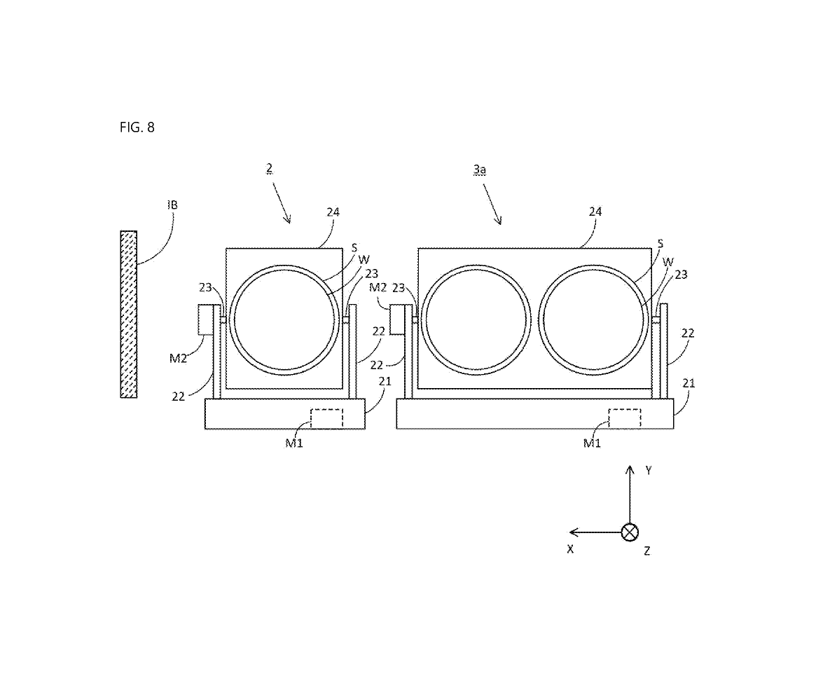

FIG. 8 is a plan view of each of the first holder 2 and a second holder 3a in the ion implanter IM2 in FIG. 7 as viewed from the Z-axis direction, according to some embodiments. The wafers W supported by each of the first holder 2 and the second holder 3a are arranged in the X-axis direction, which is the scanning direction of each holder. By arranging the wafers W in this way, the region of the ion beam IB through which each wafer W passes becomes the same.

The ion beam IB has a beam current density distribution in the Y-axis direction, which is the longitudinal direction of the ion beam IB. Ideally, the beam current density distribution of the ion beam IB is uniform in the longitudinal direction (e.g., the Y-axis direction) and has a specific value. However, in reality, the value of the beam current density distribution in the longitudinal direction of the ion beam IB may vary by about 1% to about 3%.

If the ion implantation process for wafers W is performed in the same region of the ion beam IB, there will be no variation in ion implantation process for each wafer W. In other words, the characteristics of semiconductor devices manufactured by ion implantation process may be uniform, which is advantageous for realizing the production of standardized devices.

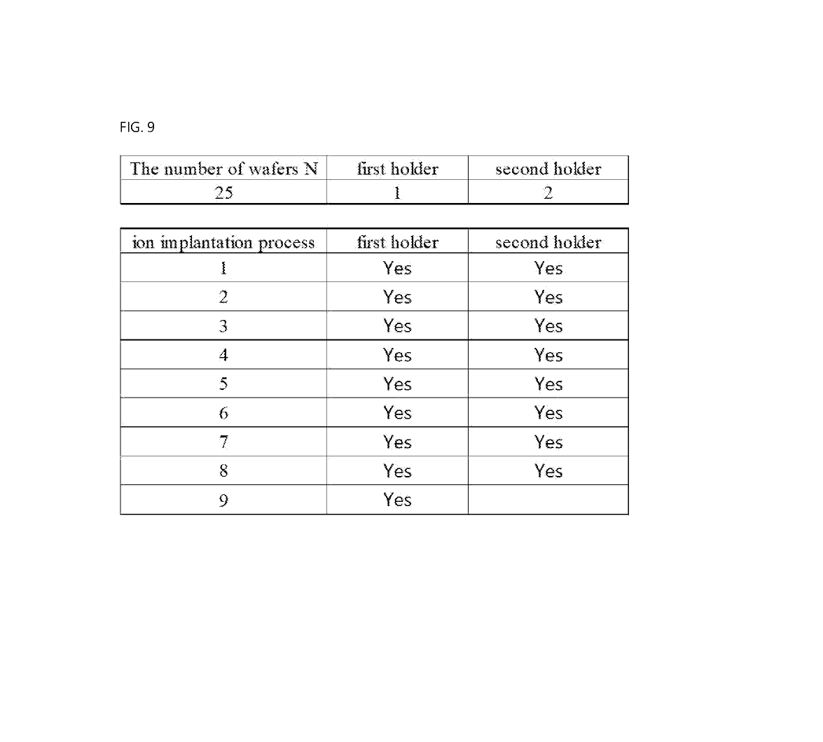

FIG. 9 is an explanatory diagram of a selection process of a controller C in the ion implanter IM2 shown in FIG. 7, according to some embodiments. The controller C selects both the first holder 2 and the second holder 3a for a first ion implantation process to an eighth ion implantation process. For the ninth ion implantation process, only the first holder 2 is selected.

As shown in some embodiments of FIGS. 1 to 9, the number of wafers W supported by the first holder 2 may be set to one, and the number of wafers W supported by the second holder 3 or the second holder 3a may be set to one or more. By selecting the first holder 2 and the second holder 3 or 3a to be scanned according to the number of wafers W to be processed and the number of wafers W supported by each of the first holder 2 and the second holder 3 or 3a, ion implantation processing can be performed without using dummy wafers.

In the configuration shown in the embodiments of FIGS. 1 to 9, there is no need for a special mechanism to retract the wafer mounting portion to a position not irradiated by the ion beam IB, as in the related art technology. As a result, the configuration of the ion implanter may be simplified.

In the configuration shown in the embodiments of FIGS. 1 to 9, a method is adopted in which each of the first holder 2 and the second holder 3 or 3a is scanned linearly across the ion beam IB. Since the configuration is such that the ion beam IB is crossed linearly, there is no bias in the amount of implantation due to differences in angular velocity within the wafer surface as in the related art technology. As a result, uniform implantation within the wafer W can be easily achieved.

The number of wafers W supported by the second holder 3 or 3a is not limited to one or two. Three or more wafers W may be supported. When the number of wafers W to be processed is N and the number of wafers supported by the second holder is M, the controller C selects the holders to be scanned so as to satisfy the relationship N = (1 + M) × A + B + M × C (where each of A, B, and C is 0 or a natural number, and not all of A, B, and C are 0). In other words, at least one of A, B, or C is not 0. In the relationship, A is the number of times both the first holder and the second holder are selected, B is the number of times only the first holder is selected, and C is the number of times only the second holder is selected.

If there are multiple combinations of A, B, and C that satisfy the relationship, the combination with a smallest sum of A, B, and C is selected. If there are multiple combinations with the smallest sum, the controller C may calculate the time used for ion implantation processing of the wafers W and may select the combination with the shortest time for processing all of the wafers W. If there is no difference in implantation time, the controller C selects the holder according to the rule stored in the storage.

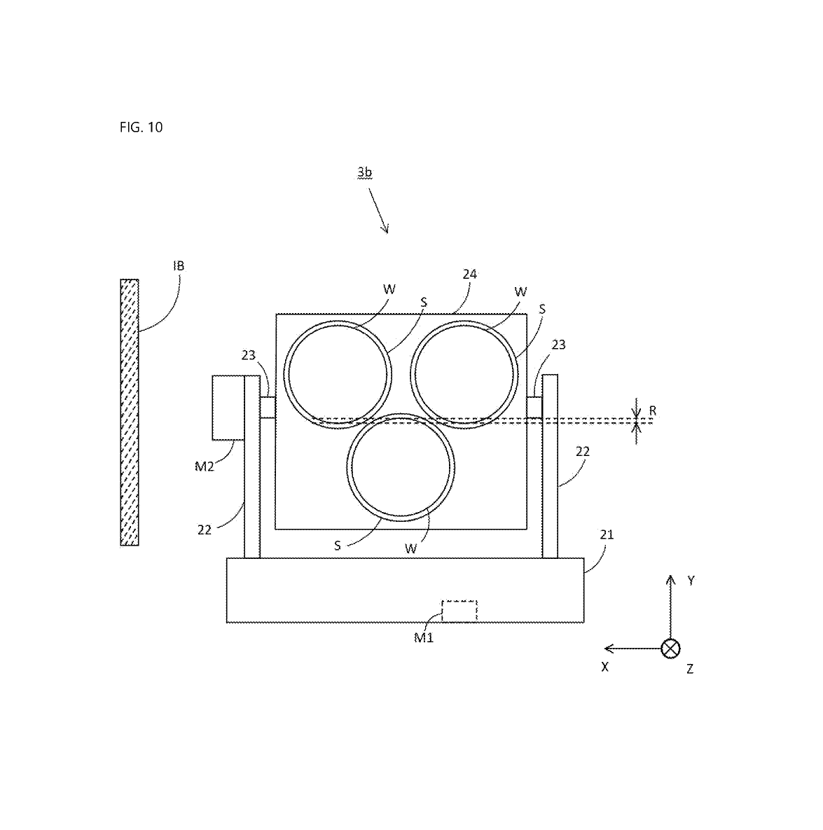

FIGS. 10 illustrates an example of a schematic plan view of the second holder 3, according to some embodiments. Regarding the support of wafers W by the second holder 3, the configuration shown in FIG. 10 may be adopted. To efficiently use the limited irradiation area of the ion beam IB and process a large number of wafers W, the wafers W supported by the second holder 3 may be arranged so that each wafer W partially overlaps in a region R when viewed from the scanning direction of the second holder 3.

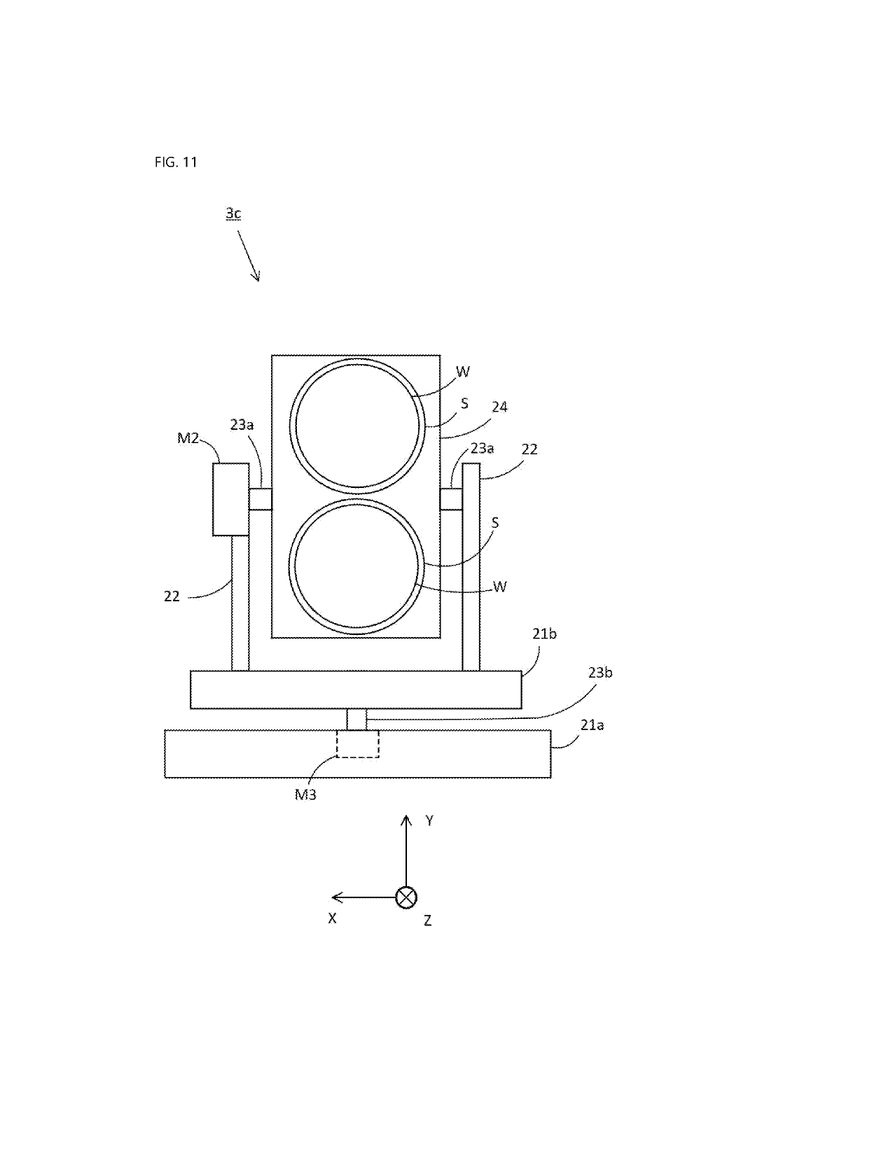

FIG. 11 illustrates an example of a schematic plan view of a second holder 3c, according to some embodiments. Regarding the support of wafers W by the second holder 3c, the configuration shown in FIG. 11 may be adopted. In the configuration shown in FIG. 11, the wafers W supported by the second holder 3c are arranged in the Y-axis direction.

In the configuration example of FIG. 11, a second base 21b supported by a rotation shaft 23b is arranged on a first base 21a. The rotation shaft 23b is rotated by a drive source M3 arranged in the first base 21a. The upper part of the second base 21b is the same as the configuration of the second holder 3 described above with respect to FIG. 2 and thus repeated description thereof is omitted for conciseness.

In the configuration shown in FIG. 11, two rotation shafts are used: a rotation shaft 23b for setting the tilt angle of the wafer W and a rotation shaft 23a for changing the posture of the support plate 24 when replacing the wafer W.

Since two rotation shafts are used, the configuration is more complicated than the configurations shown in FIGS. 2 and 8. However, regardless of the arrangement of the wafers W shown in FIG. 11, a configuration with two axes as rotation shafts may be adopted.

In the embodiments described with respect to FIGS. 1-11, the first holder 2 and the second holder 3, 3a, 3b, or 3c are scanned on a single guide rail 4. However, embodiments are not limited thereto.

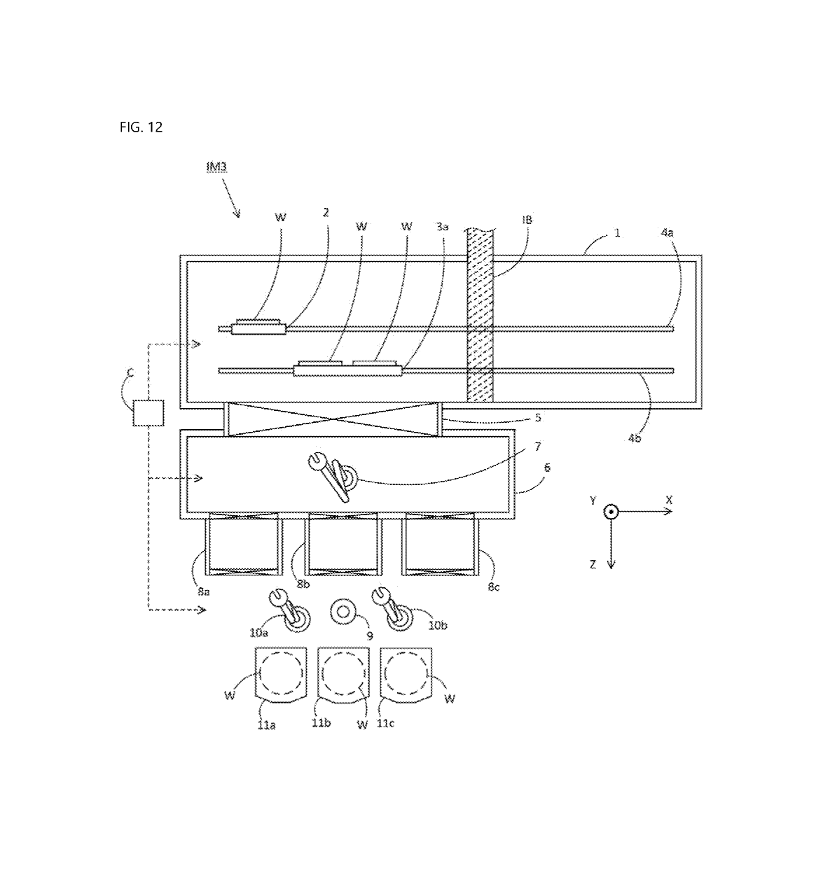

FIG. 12 illustrates an example of a schematic configuration view of an ion implanter, according to some embodiments. In an ion implanter IM3 shown in FIG. 12, a first guide rail 4a may provided for the first holder 2 and a second guide rail 4b may be provided for the second holder 3, 3a, 3b, or 3c. Although the configuration of the ion implanter becomes more complicated, a method may be adopted in which the first holder 2 and the second holder 3, 3a, 3b, or 3c are independently scanned on individual guide rails 4a and 4b.

With the configuration shown in FIG. 12, it is not necessary to retract the other holder to a non-irradiated position of the ion beam IB when scanning one holder. In the embodiments described with respect to FIGS. 1-12, the transfer of wafers W to each of the first holder 2 and the second holder 3, 3a, 3b, or 3c was performed on one side of the ion beam IB introduced into the process chamber 1. However, embodiments are not limited thereto.

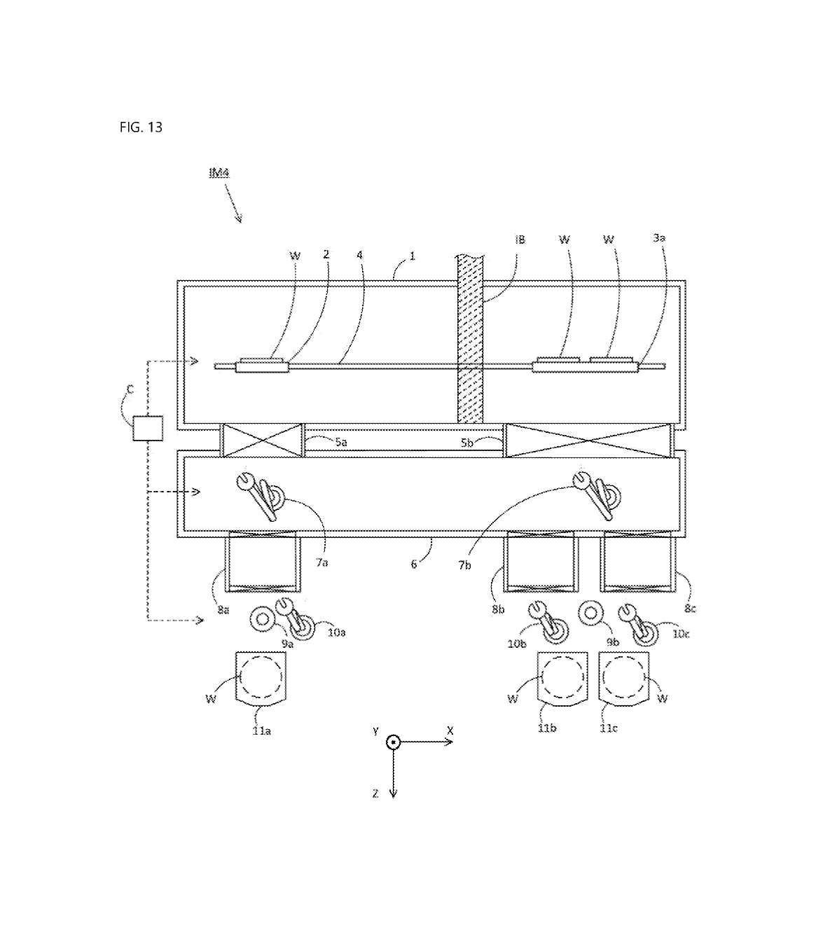

FIG. 13 illustrates an example of a schematic configuration view of an implanter, according to some embodiments. Although there are disadvantages about the complexity of the configuration of the ion implanter and an increase in footprint, as shown in an ion implanter IM4 in FIG. 13, a configuration may be adopted in which the transfer of wafers W to the first holder 2 is performed on one side of the ion beam IB introduced into the process chamber 1 (e.g., a left side of the ion beam IB in FIG. 13) and the transfer of wafers W to the second holder 3a is performed on the opposite side of the ion beam IB introduced into the process chamber 1 (e.g., a right side of the ion beam IB in FIG. 13) . In the configuration shown in FIG. 13, the valve 5 may include two valves 5a and 5b. While FIG. 13 illustrates the configuration with respect to the second holder 3a, it will be understood that, in some embodiments, the second holder 3, 3b, or 3c may also be used with the configuration illustrated in FIG. 13.

The embodiments described in FIGS. 1 to 13 are merely examples, and the number of cassettes, atmospheric transfer robots, vacuum transfer robots, load-lock chambers, and aligners is not limited to the configuration of the embodiments illustrated by way of example with respect to FIGS. 1-13. In addition, other known configurations may be adopted for the configuration of each of the first and second holders 2 and 3 and the scanning mechanism of each of the first and second holders 2 and 3. Furthermore, the longitudinal direction of the ion beam IB may be set as the X-axis direction, and the scanning direction of each of the first and second holders 2 and 3 may be set as the Y-axis direction.

In some embodiments described with respect to FIGS. 1-13, a configuration using two holders, the first holder 2 and the second holder 3, has been described. However, in some embodiments, additional holders such as a third holder and a fourth holder may be used.

In the embodiments described with respect to FIGS. 1-13, each support S of each of the first holder 2 and the second holder 3, 3a, 3b, or 3c supports a wafer W (i.e., each support S supports one wafer W). However, a configuration may be adopted in which a plurality of wafers W are supported by a single support S.

It should be understood that embodiments are not limited to the various embodiments described above, but various other changes and modifications may be made therein without departing from the spirit and scope thereof as set forth in appended claims.

What is claimed is:

1. An ion implanter comprising:
a process chamber;
two holders configured to be scanned linearly across an ion beam in the process chamber, the two holders comprising a first holder configured to support a single wafer and a second holder configured to support one or more wafers; and
a controller configured to select only the first holder, only the second holder, or both the first holder and the second holder to be scanned from the two holders during ion implantation into a plurality of wafers,
wherein the controller is configured such that, when a number of wafers of the plurality of wafers to be processed is N and a number of wafers supported by the second holder is M, the controller selects the holders to be scanned to satisfy a relationship N = (1 + M) × A + B + M × C,
wherein A is a number of times both the first holder and the second holder are selected, B is a number of times only the first holder is selected, and C is a number of times only the second holder is selected, and
wherein each of A, B, and C is 0 or a natural number, and at least one of A, B, or C is not 0.

2. The ion implanter according to claim 1,
wherein the controller is configured to select the holder to be scanned such that a sum of A, B, and C is minimized.

3. The ion implanter according to claim 2,
wherein, when there are a plurality of combinations of A, B, and C resulting in a same minimum sum, the controller is configured to select a combination of A, B, and C in which an ion implantation processing time for the N wafers is shortest.

4. The ion implanter according to claim 1,
wherein the single wafer supported by the first holder and the one or more wafers supported by the second holder are arranged in a scanning direction of each holder.

5. The ion implanter according to claim 1,
a transfer location of the single wafer to the first holder and the one or more wafers to the second holder is on a same side with respect to the ion beam.

6. The ion implanter according to claim 5,
scanning paths of the first holder and the second holder are the same, and
wherein the first holder is positioned on a side closer to the ion beam.

7. The ion implanter according to claim 1,
a first transfer location of the single wafer to the first holder and a second transfer location of the one or more wafers to the second holder are different with respect to the ion beam.

8. The ion implanter according to claim 1,
wherein the single wafer supported by the first holder and the one or more wafers supported by the second holder are scanned along a same scanning path.

9. The ion implanter according to claim 1,
wherein the single wafer supported by the first holder and the one or more wafers supported by the second holder are scanned along different scanning paths.

10. The ion implanter according to claim 9,
wherein the different scanning paths are parallel to each other.

11. The ion implanter according to claim 1,
wherein the first holder is rotated by a first rotation shaft and the second holder is rotated by a second rotation shaft,
the first rotation shaft both sets a tilt angle of the first holder and changes an orientation of the first holder during wafer exchange, and
the second shaft both sets a tilt angle of the second holder and changes an orientation of the second holder during wafer exchange.

12. The ion implanter according to claim 1, further comprising:
one or more transfer chambers, and
one or more valves respectively between the one or more transfer chambers and the process chamber,
wherein one valve of the one or more valves has a size to transfer multiple wafers simultaneously arranged in a horizontal line between a transfer chamber of the one or more transfer chambers that corresponds to the one valve and the process chamber.

13. The ion implanter according to claim 12,
wherein the multiple wafers are transferred to the first holder and the second holder.

14. The ion implanter according to claim 1, further comprising:
multiple load-lock chambers.

15. The ion implanter according to claim 1, wherein N is twenty-five.

16. An ion implanter comprising:
a process chamber;
two holders configured to be scanned linearly across an ion beam in the process chamber during an ion implantation of a plurality of wafers, the ion implantation including a plurality of ion implantation processes, the two holders comprising a first holder configured to support a single wafer and a second holder configured to support one or more wafers; and
a controller configured to select, for each ion implantation process of the plurality of ion implantation processes, only the first holder, only the second holder, or both the first holder and the second holder to be scanned,
wherein when a number of wafers of the plurality of wafers to be processed is N and a number of wafers supported by the second holder is M, the ion implantation of the plurality of wafers satisfies a relationship N = (1 + M) × A + B + M × C,
wherein A is a number of times both the first holder and the second holder are selected during the ion implantation, B is a number of times only the first holder is selected during the ion implantation, and C is a number of times only the second holder is selected during the ion implantation, and
wherein each of A, B, and C is 0 or a natural number, and at least one of A, B, or C is not 0.
